(19) United States
(12) Patent Application Publication
(10) Pub. No.: US 2019/0149134 A1
(43) Pub. Date: May 16, 2019

(54) FILTER OPTIMIZATION TO IMPROVE COMPUTATIONAL EFFICIENCY OF CONVOLUTION OPERATIONS

(71) Applicant: Intel Corporation, Santa Clara, CA (US)

(72) Inventors: Changwon Daniel Rhee, Rocklin, CA (US); Wei Xiong, Fremont, CA (US); Hongzheng Li, Sunnyvale, CA (US)

(73) Assignee: Intel Corporation, Santa Clara, CA (US)

(21) Appl. No.: 16/246,913

(22) Filed: Jan. 14, 2019

(51) Int. Cl. H03H 17/02; G06F 17/15; G06F 17/16

(52) U.S. Cl. CPC H03H 17/0238; G06F 17/15; G06N 3/04; H03H 17/0225; G06F 17/16

(57) ABSTRACT

Various embodiments are generally directed to techniques for optimizing convolution filters. Generally, embodiments may determine, based on an analysis of a plurality of values of a convolution filter, an optimization operation to optimize at least one value of the plurality of values of the convolution filter. Embodiments may perform the optimization operation on the values of the convolution filter to generate an optimized convolution filter. Embodiments may also perform a convolution operation by a convolution logic based on the optimized convolution filter and an input data.

### TECHNICAL FIELD

Embodiments herein generally relate to convolution operations, and more specifically, to optimizing convolution filters to improve the computational efficiency of convolution operations.

### BACKGROUND

Convolution operations are often the most computationally expensive operations in machine learning and/or signal processing applications. For example, convolution operations may require millions or even billions of multiplication, addition, and multiply-accumulate (MAC) operations. Depending on the processor, these operations may result in non-real-time performance, long latency, and high power consumption. Indeed, some processors simply cannot support such features or applications. Building more powerful processors or relying on secondary resources may alleviate these problems, however, doing so would increase system costs and complexity.

### BRIEF DESCRIPTION OF THE DRAWINGS

FIG. 1 illustrates an embodiment of a system.

FIGS. 2A-2D illustrate embodiments of optimizing filters to improve the computational efficiency of convolution operations.

FIG. 3 illustrates an embodiment of a first logic flow.

FIG. 4 illustrates an embodiment of a second logic flow.

FIG. 5 illustrates an embodiment of a third logic flow.

FIG. 6A illustrates an embodiment of a fourth logic flow

FIG. 6B illustrates an embodiment of a fifth logic flow.

FIG. 7 illustrates an embodiment of a storage medium.

FIG. 8 illustrates an embodiment of a computing architecture.

### DETAILED DESCRIPTION

Various embodiments are generally directed to reducing the amount of computations required for a wide range of convolution filters while keeping the underlying convolution functionality unchanged. Generally, embodiments disclosed herein generate optimized convolution filters such that the filter weights have lower variance and/or increased occurrences of zero values as filter weights. Furthermore, the optimized convolution filters may have increased numbers of identical non-zero weight values. The optimized convolution filters result in simpler mathematical operations when computing convolution operations relative to unoptimized filters. Doing so improves system performance while keeping the convolution result unchanged. For example, the optimized filters disclosed herein may result in increased throughput, lower latency, reduced cost, reduced power consumption, and the use of fewer computational resources in performing convolution operations.

With general reference to notations and nomenclature used herein, one or more portions of the detailed description which follows may be presented in terms of program procedures executed on a computer or network of computers. These procedural descriptions and representations are used by those skilled in the art to most effectively convey the substances of their work to others skilled in the art. A procedure is here, and generally, conceived to be a self-consistent sequence of operations leading to a desired result. These operations are those requiring physical manipulations of physical quantities. Usually, though not necessarily, these quantities take the form of electrical, magnetic, or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, these manipulations are often referred to in terms, such as adding or comparing, which are commonly associated with mental operations performed by a human operator. However, no such capability of a human operator is necessary, or desirable in most cases, in any of the operations described herein that form part of one or more embodiments. Rather, these operations are machine operations. Useful machines for performing operations of various embodiments include general purpose digital computers as selectively activated or configured by a computer program stored within that is written in accordance with the teachings herein, and/or include apparatus specially constructed for the required purpose. Various embodiments also relate to apparatus or systems for performing these operations. These apparatuses may be specially constructed for the required purpose or may include a general-purpose computer. The required structure for a variety of these machines will be apparent from the description given.

Reference is now made to the drawings, wherein like reference numerals are used to refer to like elements throughout. In the following description, for purpose of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modification, equivalents, and alternatives within the scope of the claims.

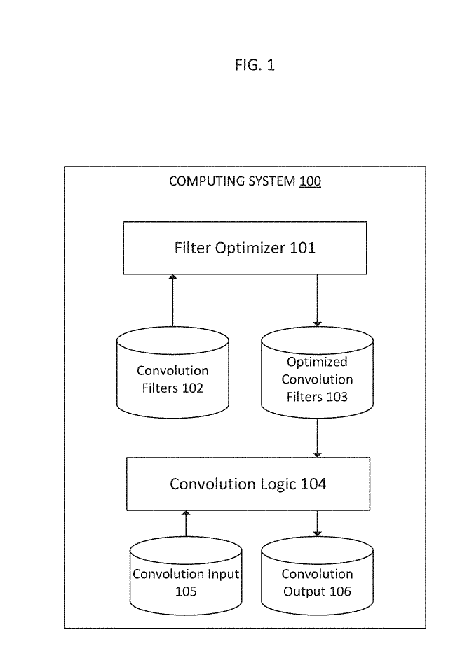

FIG. 1 illustrates an embodiment of a computing system 100. The system 100 may be any type of computing system, such as a server, workstation, laptop, compute cluster, or virtualized computing system. As another example, the system 100 may be an embedded system such as a deep learning accelerator card, a processor with deep learning acceleration, a neural compute stick, or the like. In some examples, the system 100 comprises a System on a Chip (SoC) and, in other embodiments, the system 100 includes a printed circuit board or a chip package with two or more discrete components.

As shown, the computing system 100 includes a filter optimizer 101, a convolution logic 104, and data stores of convolution filters 102, optimized convolution filters 103, convolution input 105, and convolution output 106. The configuration of the computing system 100 depicted in FIG. 1 should not be considered limiting of the disclosure, as the disclosure is applicable to other configurations. For example, one or more components of the computing system 100 may be located on different computing systems 100. As another example, the functionality of one or depicted components of the computing system 100 may be consolidated into a single component.

The filter optimizer 101 is generally configured to generate one or more optimized convolution filters 103 based on an analysis of one or more input convolution filters 102. The filter optimizer 101 may additionally and/or alternatively optimize the convolution logic 104 based on the optimized convolution filters 103. A convolution filter (also referred to as a convolution kernel) is generally a matrix of values (e.g., integer values, floating point values, etc.) of a predetermined size (e.g., a 2×2 matrix, a 3×3 matrix, etc.). Once generated, the convolution logic 104 may use the optimized convolution filters 103 to perform convolution operations on a convolution input 105, thereby generating a convolution output 106.

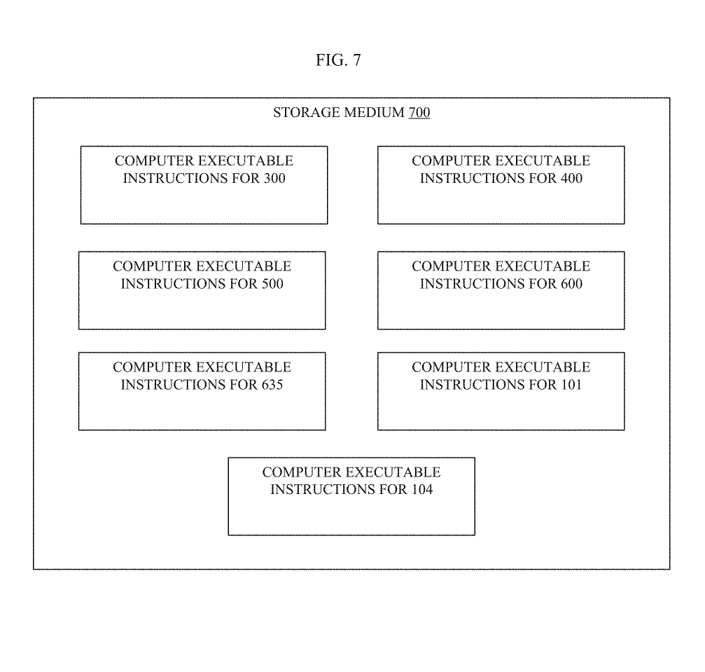

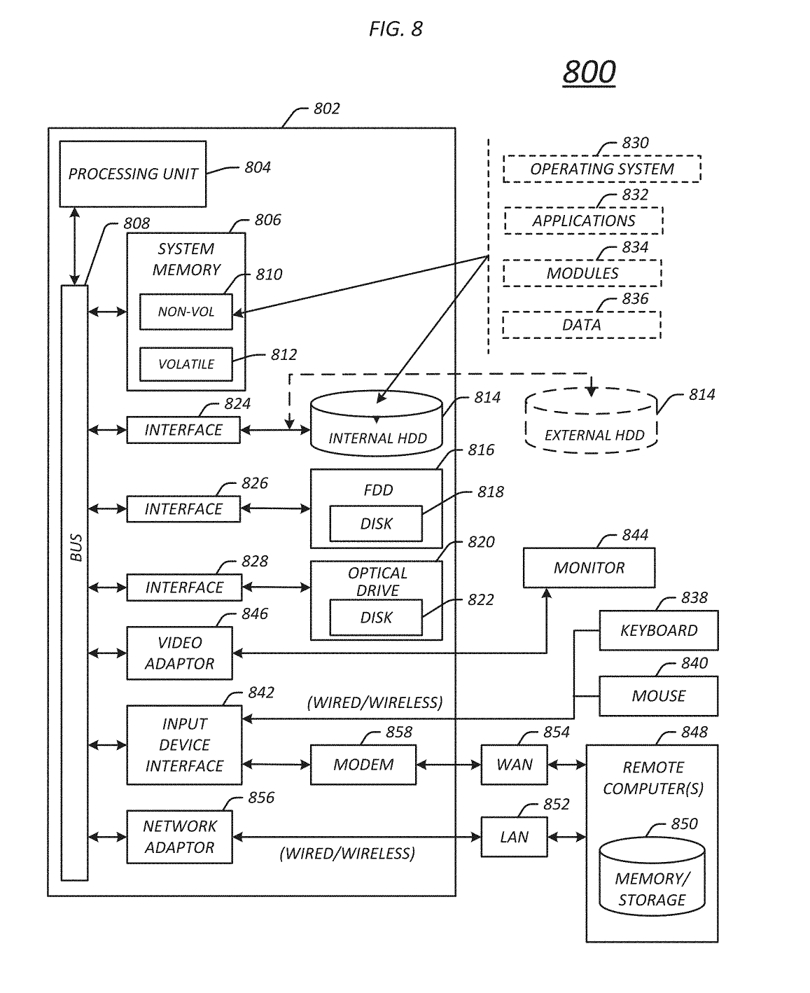

The filter optimizer 101, convolution filters 102, optimized convolution filters 103, convolution logic 104, convolution input 105, and convolution output 106 are representative of hardware, software, and/or a combination of hardware and software. For example, in hardware-based embodiments, the filter optimizer 101, convolution filters 102, optimized convolution filters 103, convolution logic 104, convolution input 105, and convolution output 106 may be at least a portion of hardware in a processor (e.g., the processing unit 804 of FIG. 8), a graphics processing unit (GPU), field programmable gate array (FPGA), etc. Similarly, in software-based embodiments, the filter optimizer 101, convolution filters 102, optimized convolution filters 103, convolution logic 104, convolution input 105, and convolution output 106 may be software stored in a memory (e.g., the memory 806 of FIG. 8) or other computer-readable storage medium (e.g., the storage medium 700 of FIG. 7).

The convolution logic 104 may be representative of any type of logic that performs convolution operations by applying a filter to input data, such as a machine learning algorithm, neural network (e.g., a convolutional neural network (CNN)), signal processing applications, and the like. The convolution logic 104 may implement any number and type of convolution operations, such as spatial dot products, fast Fourier transform (FFT), implementations of the Coppersmith-Winograd algorithm, and the like.

For example, in an embodiment where the convolution logic 104 is a CNN configured to analyze images, the convolution input 105 is image data, and the convolution output 106 is a feature map generated by one or more convolution layers of the CNN. More specifically, for an example 5×5 image matrix as convolution input 105 and a 3×3 optimized convolution filter 103, the convolution output 106 is a 3×3 output matrix. The 3×3 output matrix is generated by applying the 3×3 filter 103 to patches of the 5×5 image matrix, where the filter is shifted by a stride (e.g., a predefined number of pixels (or matrix elements), such as 1 pixel, 2 pixels, etc.) until the filter has been applied to all patches of the image matrix.

More generally, the convolution logic 104 may provide a CNN with cascaded stages for face detection, character recognition, speech recognition, or the like. The CNN may perform a training phase based on an input dataset (e.g., images of faces, handwriting, printed information, etc.) that is in the form of tensor data. The training may produce one or more convolution filters 102. For example, the convolution filters 102 may specify features that are characteristic of numerals and/or each letter in the English alphabet. However, the convolution filters 102 may comprise other types of filters (e.g., user-defined filters, filters received via a network, etc.). The filter optimizer 101 may then generate one or more optimized convolution filters 103 based on the convolution filters 102. The filter optimizer 101 may further optimize the convolution logic 104 including the CNN based on the optimized convolution filters 103. During an inference or runtime phase, the CNN of the convolution logic 104 may receive images as convolution input 105, and perform a convolution operation on the input images to generate the convolution output 106. For example, the input images may depict handwriting, and the convolution logic 104 may be used to identify numerals and/or letters of the English alphabet included in the handwriting.

The filter optimizer 101 may perform any number and type of optimization operations to generate the optimized convolution filters 103. Generally, the filter optimizer 101 may analyze the spatial redundancy and the localized weight distribution of the values of the convolution filters 102 to generate filter values that have a smaller variance. Doing so may result in optimized convolution filters 103 that have increased occurrences of zero values and/or increased occurrences of identical non-zero values. In at least one embodiment, the filter optimizer 101 may optimize all weights belonging to the convolution filter 102. However, in other embodiments, the filter optimizer 101 may optimize a portion (or less than all) of the values of the convolution filter 102.

For example, to generate an optimized convolution filter 103, the filter optimizer 101 may perform a first optimization operation to reduce the spatial redundancy of the values of a convolution filter 102, a second optimization operation to suppress the values of the convolution filter 102, and/or a third optimization operation to optimize identical values in the convolution filter 102. As stated, the filter optimizer 101 may further optimize the convolution logic 104 (e.g., optimize executable code of the convolution logic 104 and/or a hardware logic implementation of the convolution logic 104). Depending on an analysis of the spatial correlation of the values in the convolution filter 102, the filter optimizer 101 may perform any combination of optimization operations. More generally, the filter optimizer 101 selects the combination of optimization operations that results in the greatest performance improvement for the convolution logic 104 when performing convolution operations using the optimized convolution filter 103. The performance improvement may be based on one or more performance indicators. In at least one embodiment, the performance indicator includes the number of computation operations that would be required to perform a convolution operation using the different variants of optimized convolution filter 103 and/or the convolution logic 104 generated based on each combination of optimization operations. In addition and/or alternatively, the performance indicator includes an amount of time required to perform a convolution operation using the different variants of optimized convolution filter 103 and/or the convolution logic 104 generated based on each combination of optimization operations, where the lowest time is indicative of improved performance. In addition and/or alternatively, the performance indicator includes an amount of computing resources (e.g., CPU, memory, network, I/O, etc.) required to perform a convolution operation using the different variants of optimized convolution filter 103 and/or the convolution logic 104 generated based on each combination of optimization operations, where fewer resources used is indicative of improved performance. In addition and/or alternatively, the performance indicator includes latency, bandwidth, and power (or energy) consumption, where lower values for these indicators indicate improved performance.

For example, if the analysis identifies a strong spatial correlation between the values of the convolution filter 102, the filter optimizer 101 may perform each optimization operation. By performing the first optimization operation, the filter optimizer 101 may reduce the spatial redundancy of the values of the convolution filter 102, which lowers the variance of the values of the convolution filter 102. Doing so may further increase the likelihood of having identical weight values in the filter. The filter optimizer 101 may then perform the second optimization operation to identify and suppress the most frequently occurring weight values to zero, resulting in more values for which no addition, multiplication, and/or MAC operations are required during convolution. The filter optimizer 101 may then further improve the efficiency of the convolution logic 104 by taking advantage of multiple instances of the same non-zero weight values in the optimized convolution filter 103. For example, the filter optimizer 101 (or another component of the system 100) may configure the convolution logic 104 to compute a sum of products with a product of sums. Therefore, in such an example, if the optimized convolution filter 103 has weight values [w₀, w₁, . . . , wₙ] that are identical non-zero values, and [x₀, x₁, . . . , xₙ] are input values from the input 105, the convolution logic 104 may be configured to compute a product of sums ((x₀+x₁+ . . . +xₙ)*w₀), which requires fewer addition and multiplication operations than computing the sum of products ((w₀*x₀)+(w₁*x₁)+ . . . +(wₙ*xₙ)). Doing so generates an instance of the convolution logic 104 that has a reduced number of instructions (and/or operations) relative to unoptimized instances of the convolution logic 104.

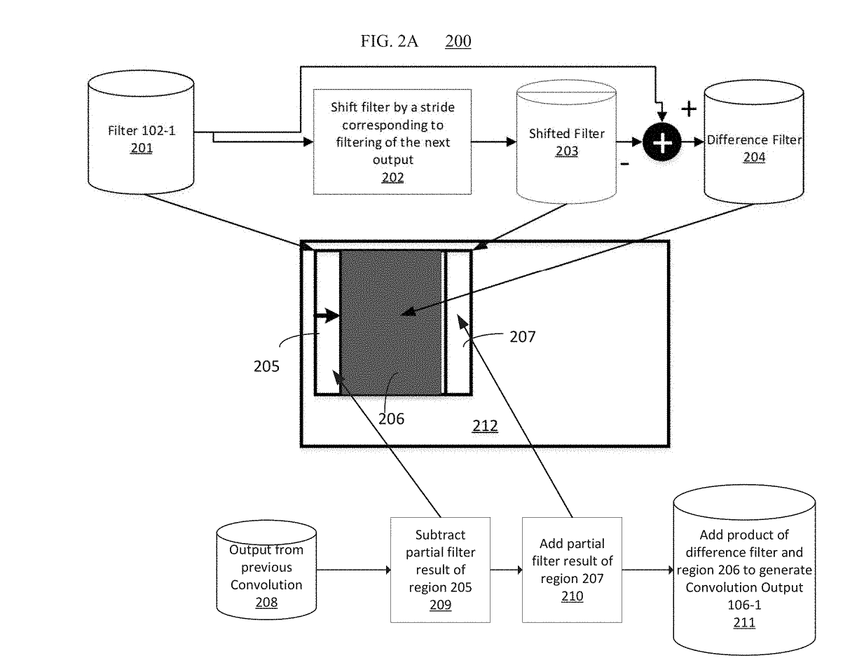

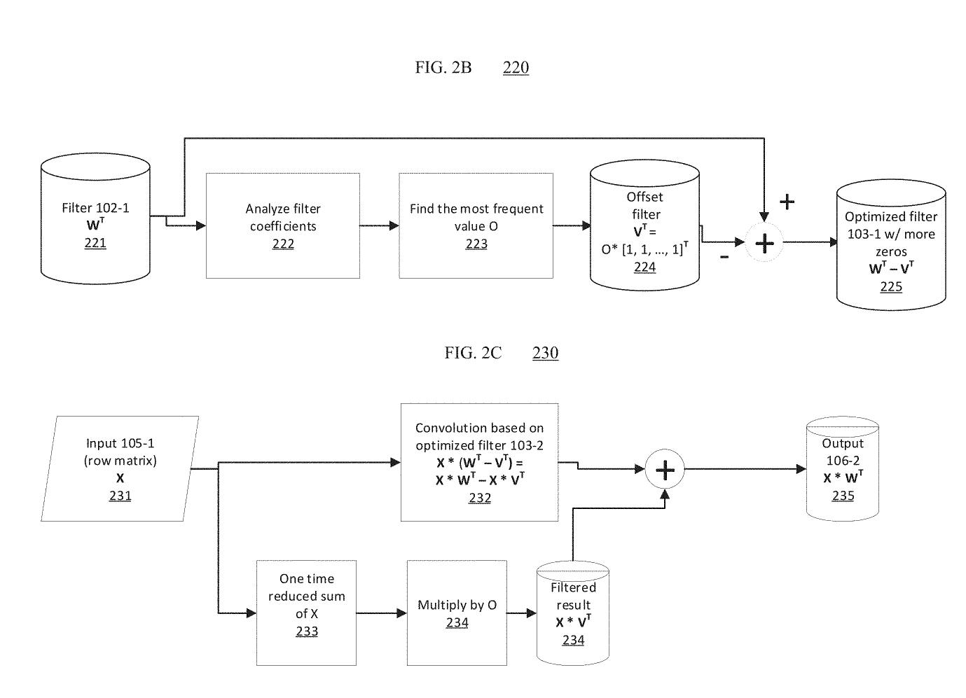

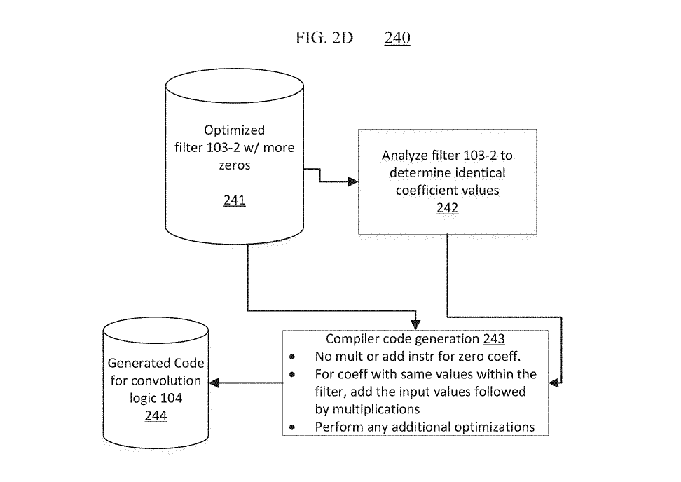

FIG. 2A is a schematic 200 depicting operations performed by the filter optimizer 101 to generate an optimized convolution filter using the first filter optimization operation to reduce spatial redundancy, according to one embodiment. In the example depicted in FIG. 2A, the 1D input convolution filter 102-1 may include weight values [w₀, w₁, w₂, w₃], while the input of a 1D input image 105 includes values [x₀, x₁, x₂, x₃, x₄, . . . , xₙ], where “n” is any positive integer. Generally, in the first optimization operation, the filter optimizer 101 may receive a convolution filter 102-1 at block 201. At block 202, the filter optimizer 101 may then shift the filter 102-1 by a stride (e.g., one value, two values, etc.), generating a shifted filter 203. The shifted filter 203 is subtracted from the filter 102-1, thereby generating a difference filter 204. The difference filter 204 may therefore be represented as [(w₁−w₀), (w₂−w₁), (w₃−w₂)]. The difference filter 204 has a lower variance of values relative to the original filter 102-1, which increases the likelihood that two or more elements of the difference filter 204 have identical weights.

FIG. 2A further depicts how the convolution logic 104 computes a dot product convolution using the difference filter 204 and an input image 212 as convolution input 105. Generally, if the difference filter 204 is used, the convolution logic 104 generates a partial delta value between two corresponding convolution outputs. Given the adjacent convolution outputs, the current output can be computed using the output of the difference filter 204.

As shown at block 208, the output of the convolution of the convolution filter 102-1 and regions 205 and 206 of the input image 212 is computed. Therefore, at block 208, the previous output is equal to [w₀×₀+w₁×₁+w₂×₂+w₃×₃]. Region 205 represents a portion of the input image 212 that “leaves” the window (in this example, “x₀”) when the convolution filter is shifted by a stride at block 202. Similarly, region 207 corresponds to the portion of the input image 212 that enters the window (in this example, “x₄”) when the convolution filter is shifted by a stride. The amounts of data in regions 205 and 207 are the same. Region 206 represents a portion of the input image 212 that remains in the window before and after the convolution filter is shifted by a stride.

At block 209, the products of weights in the input filter 102-1 and the region 205 are subtracted from the output of block 208. This may be represented by (w₀×x₀) using the 1D examples of FIG. 2A. At block 210, the products of weights in the input filter 102-1 and the region 207 is computed (represented by (w₃×x₄)), and added to the output of block 210, producing a partial result. At block 211, a product of the difference filter 204 and the data of region 206 is computed, which is then added to the intermediate result from block 210 to produce the current convolution output 106-1 (e.g., a feature map). This process may be repeated to complete the entire convolution for the input image 212. Continuing with the 1D example, the output generated at block 211 may be represented by the following operations:

Current output=[(w₀×x₀)+(w₁×x₁)+(w₃×x₃)]−(w₀×x₀)+(w₃×x₄)−[x₁(w₁−w₀)+x₂(w₂−w₁)+x₃(w₃−w₂)]. Equation 1.

Equation 1 reduces to:

Current output=(w₁×x₁)+(w₂×x₂)+(w₃×x₃)+(w₃×x₄)−[x₁(w₁−w₀)+x₂(w₂−w₁)+x₃(w₃−w₂). Equation 2.

Equation 2 in turn reduces to:

Current output=(x₁×w₀)+(x₂×w₁)+(x₃×w₂)+(x₄×w₃). Equation 3.

In at least one embodiment, the convolution logic 104 may be optimized by including instructions and/or logic to implement equation 3 (or a similar equation).

FIG. 2B is a schematic 220 depicting operations performed by the filter optimizer 101 to generate an optimized convolution filter 103-2 using the second filter optimization operation to suppress filter weights, according to one embodiment. Generally, the filter optimizer 101 identifies the most frequently occurring value in a filter and forces these values to zero by subtracting the identified frequently occurring value from all values in the filter.

As shown in FIG. 2B, the filter optimizer 101 may receive an input filter at block 221. The received input filter may be an unoptimized filter (e.g., a convolution filter 102-1 from the convolution filters 102), or a filter generated using the first optimization operation (e.g., the difference filter 204 of FIG. 2A). The filter received at block 221 may be represented by W^{T} in FIGS. 2B-2C. At block 222, the filter optimizer 101 analyzes the values (or coefficients) of the filter W^{T} received at block 221. For example, the filter optimizer 101 may generate a histogram of the values in the filter W_{T}. The histogram may reflect the frequency by which each of a plurality of values (e.g., values ranging from 0-255 for 8-bit integer filter weights) appears in the filter W^{T}. At block 223, the filter optimizer 101 identifies the most frequently occurring value O in the values of the filter W^{T}. For example, the filter optimizer 101 may identify the value of 121 as the most frequently occurring value based on the histogram.

At block 224, the filter optimizer 101 computes an offset filter V^{T}, which may be computed by multiplying the most frequently occurring value O to a constant matrix. In one embodiment, each element the constant matrix has a value of 1. At block 225, an optimized convolution filter 103-1 is computed by subtracting V^{T} from W^{T} (e.g., W^{T}−V^{T}). Since 0 is the most commonly occurring value in W^{T}, the optimized convolution filter 103-2 represented by W^{T}−V^{T} has the same or more zero values than W^{T}, and no operations are required to perform a convolution on these values (e.g., addition and/or multiplication by zero is unnecessary). Therefore, for example, a compiler (not pictured) may refrain from generating code statements for these operations when compiling the convolution logic 104, and the convolution logic 104 generated by the compiler would not waste time and/or resources performing unnecessary operations.

FIG. 2C is a schematic 230 illustrating an example convolution operation performed by the convolution logic 104 using the optimized filter 103-2 of FIG. 2B, according to one embodiment. As shown, convolution input 105-1 may be received at block 231. The input 105-1 may be an input matrix corresponding to a portion of an input image, and may be referred to as X to discuss the example depicted in FIG. 2C. At block 232, the convolution logic 104 performs convolution operations based on the input data 105-1 and the optimized filter 103-2. This may be represented as X×(W^{T}−V^{T}), which in turn may be represented as (X×W^{T})−(X×V^{T}). To undo the effect of “−V^{T}” introduced at block 232, at block 233, the convolution logic 104 may compute a one-time reduced sum of the values of the input data 105-1. For example, if X=[x₀, x₁, . . . , xₙ], the sum computed at block 233 is equal to [x₀+x₁+ . . . +xₙ]. At block 234, the convolution logic 104 multiplies the most frequently occurring value O identified at block 223 of FIG. 2B by the one-time reduced sum computed at block 233. This may be represented by O×[x₀+x₁+ . . . +xₙ]. At block 234, the convolution logic 104 computes a filtered result, namely X×V^{T}. At block 235, the convolution logic 104 computes the final output 106-2 by adding the output of blocks 232 and 234, which results in the desired output of X×W^{T}.

FIG. 2D is a schematic 240 illustrating an optimization operation to optimize identical weights and an optimization operation to optimize the convolution logic 104. As shown, at block 241, the filter optimizer 101 receives a filter. The filter may be an unoptimized convolution filter 102, the optimized filter 103-1, the difference filter 204, and/or a different type of optimized filter 103. At block 242, the filter optimizer 101 analyzes the filter received at block 242 to determine one or more identical non-zero values therein. For example, based on a histogram generated for the values in the filter received at block 242, the filter optimizer 101 may determine that the values 2, 50, and 100 each occur more than once. By identifying these values, executable code generated by a compiler for the convolution logic 104 at block 243 may be optimized. For example, the compiler may generate executable code for the convolution logic 104 that does not include instructions for operations that would multiply zero values in the optimized filters 103 with values of the convolution input 105. As another example, the compiler may generate executable code for the convolution logic 104 that does not include instructions for operations that would add zero values in the optimized filters 103 to values of the convolution input 105. As yet another example, the compiler would replace “sum of product” operations for the convolution logic 104 with “product of sum” operations for identical non-zero values in the optimized filter 103. The output of the code generation block 243 is depicted at block 244, which includes the generated executable code for the convolution logic 104. Although depicted as executable code, as stated, in embodiments where the convolution logic 104 is implemented in hardware, the hardware implementation of the convolution logic 104 may be similarly optimized (e.g., to eliminate redundant operations, optimizing mathematical operations, etc.).

To further illustrate the advantages introduced when the filter optimizer 101 generates optimized convolution filters 103, an example of the convolution logic 104 performing a Winograd convolution using an optimized convolution filter 103 is presented. For example, a f(2×2, 3×3) Winograd convolution may use an optimized convolution filter 103 of size 3×3, and the size of the convolution output 106 is 2×2. In such an example, the following Equation 4 includes element-wise multiplication to perform the Winograd convolution:

Y=A^{T}[[GgG^{T}]·[B^{T}dB]]A Equation 4

In equation 4, the following definitions apply:

$${B}^{T} = [ \begin{matrix}1 & 0 & - 1 & 0 \\ 0 & 1 & 1 & 0 \\ 0 & - 1 & 1 & 0 \\ 0 & 1 & 0 & - 1\end{matrix} ] , G = [ \begin{matrix}1 & 0 & 0 \\ \frac{1}{2} & \frac{1}{2} & \frac{1}{2} \\ \frac{1}{2} & - \frac{1}{2} & \frac{1}{2} \\ 0 & 0 & 1\end{matrix} ] , and$$

$${A}^{T} = [ \begin{matrix}1 & 1 & 1 & 0 \\ 0 & 1 & - 1 & - 1\end{matrix} ]$$

In equation 4, “g” corresponds to the 3×3 optimized convolution filter 103 and “d” is the 4×4 input matrix from the convolution input 105. The “·” corresponds to an element-wise multiplication operation. By suppressing the coefficients in “g” to zeroes, some operations in the transform of [GgG^{T}] can be avoided. Furthermore, depending on which filter coefficients are suppressed, some of the element-wise multiplications can be avoided, which also means that the corresponding input data transformation operation can be further avoided in [B^{T} dB]. Further still, some inverse transform operations can be avoided in A^{T}[[GgG^{T}]·[B^{T} dB]]A. Therefore, the convolution logic 104 generated to implement the above Winograd convolution operation would benefit from improved performance by including a reduced number of multiplication, addition, and MAC instructions.

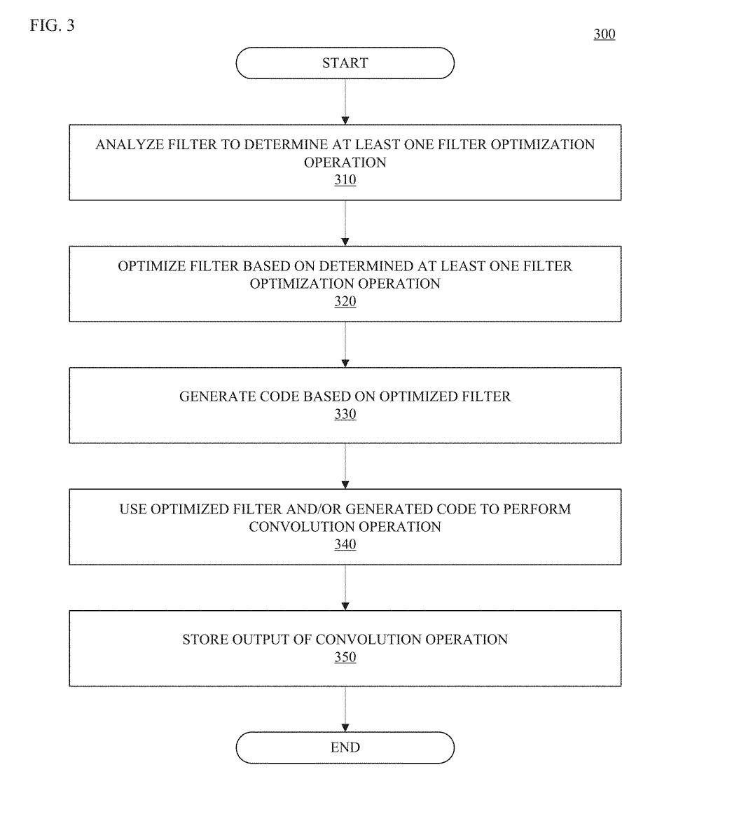

FIG. 3 illustrates an embodiment of a logic flow 300. The logic flow 300 may be representative of some or all of the operations executed by one or more embodiments described herein. For example, the system 100 may perform the logic flow 300 to generate optimized filters 103 and perform convolution operations using the optimized filters 103. Embodiments are not limited in this context.

As shown, the logic flow 300 begins at block 310, where the filter optimizer 101 determines at least one filter optimization operation. As stated, the filter optimizer 101 may implement one or more optimization operations based on an analysis of the values of a convolution filter 102. For example, the filter optimizer 101 may analyze a convolution filter 102 to determine whether the values in the convolution filter 102 have strong spatial correlation. As another example, the filter optimizer 101 may determine a performance indicator for each permutation of the one or more optimization operations. For example, the performance indicator may include one or more of an amount of time, an amount of computing resources, and a number of operations required by the convolution logic 104 to perform a convolution operation using an optimized filter 103 generated based on each permutation of the one or more of the optimization operations. For example, the filter optimizer 101 may select the at least one filter optimization operation that results in the fewest number of operations, the least amount of time, and/or the least amount of resources to perform the convolution operation by the convolution logic 104.

At block 320, the filter optimizer 101 generates an optimized convolution filter 103 based on a convolution filter 102 and the at least one filter optimization technique determined at block 320. For example, the filter optimizer 101 may reduce spatial redundancy of the convolution filter 102, suppress filter weights in the convolution filter 102, and/or optimize identical weights of the convolution filter 102. At block 330, a compiler may generate executable code for the convolution logic 104 that is optimized based on the optimized filter 103. Generally, the compiler may refrain from generating executable statements for add by zero operations, multiply by zero operations, and may further modify executable statements to include the least number of operations (e.g., replace a sum of products with a product of sums).

At block 340, the convolution logic 104 uses the optimized filter 103 to perform a convolution operation on input convolution data 105. For example, the convolution logic 104 may perform signal processing convolutions, machine learning convolutions, etc. At block 350, the convolution logic 104 may store the output of the convolution operation as the convolution output 106.

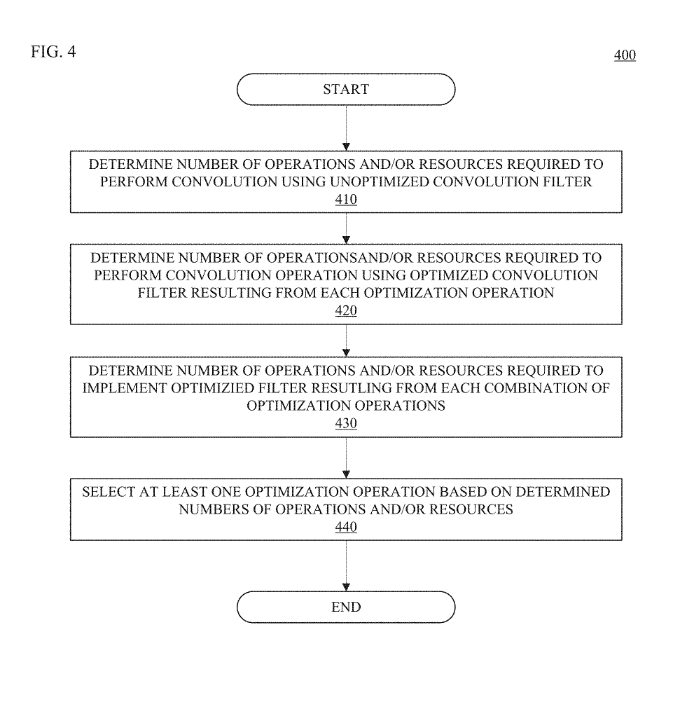

FIG. 4 illustrates an embodiment of a logic flow 400. The logic flow 400 may be representative of some or all of the operations executed by one or more embodiments described herein. For example, the filter optimizer 101 may perform the logic flow 400 to select one or more optimization operations for generating an optimized convolution filter 103 and/or optimizing the convolution logic 104. Embodiments are not limited in this context.

As shown, at block 410, the filter optimizer 101 determines a number of operations and/or resources required to implement a convolution operation using an unoptimized filter 102. The number of operations may be determined by analyzing the executable code of an instance of the convolution logic 104 generated using an unoptimized convolution filter 102. At least part of the analysis of the executable code may include determining a number of addition, multiply, and/or MAC operations in the executable code for the convolution logic 104. This may provide a baseline number of operations used by the filter optimizer 101 for comparison when selecting an optimization operation to generate optimized convolution filters 103. The resources may include time, computing resources, and the like. The filter optimizer 101 may perform simulations to determine the amount of time, power, and/or resources required to perform the convolution operation using the unoptimized filter 102. In at least one embodiment, a user may provide input specifying the number of operations at blocks 410-430.

At block 420, the filter optimizer 101 determines the number of operations and/or the amount of resources required to perform a convolution operation using an optimized convolution filter 103 generated based on each optimization operation. The number of operations may be determined by analyzing the executable code of an instance of the convolution logic 104 generated using the optimized convolution filters 103. At least part of the analysis of the executable code convolution logic 104 may include determining a number of addition, multiply, and/or MAC operations in the executable code for an instance of the convolution logic 104 compiled based on each type of optimized convolution filter 103. The analysis may further include determining the required amounts of time, computing resources, and the like. The filter optimizer 101 may perform simulations to determine the amount of time, power, and/or computing resources required to perform the convolution operation using the optimized convolution filter 103 generated based on each optimization operation.

At block 430, the filter optimizer 101 determines the number of operations and/or the amount of resources required to perform a convolution operation using an optimized convolution filter 103 generated based on each combination (or permutation) of the optimization operations. This allows the filter optimizer 101 to determine the effect of combining two or more of the optimization operations. At least part of the analysis of the executable code may include determining a number of addition, multiply, and/or MAC operations in the executable code for an instance of the convolution logic 104 compiled based on each convolution filter 103 generated based on combinations of two or more of the optimization operations. The analysis may further include determining the required amounts of time, computing resources, and the like. The filter optimizer 101 may perform simulations to determine the amount of time, power, and/or resources required to perform the convolution operation using the optimized convolution filter 103 generated based on each combination of optimization operations.

At block 440, the filter optimizer 101 selects at least one optimization operation based on the numbers of operations, amounts of time, amounts of power consumption, and/or amounts of computing resources determined at blocks 410-430. For example, the filter optimizer 101 may determine that using the spatial redundancy optimization operation would require 2 million operations, using the suppression of filter weights optimization operation would require 3 million operations, and a combination of the two operations would require 1.5 million operations. Therefore, the filter optimizer 101 may select the combination of spatial redundancy and suppression of filter weights to generate optimized convolution filters 103, as this results in an instance of the convolution logic 104 that includes the fewest number of addition, multiplication, and/or MAC operations. As another example, the filter optimizer 101 may determine that using the spatial redundancy optimization operation would require 1 kilowatt hour (kWh) of power, using the suppression of filter weights optimization operation would require 3 kWh of power, and a combination of the two operations would require 1.5 kWh of power. Therefore, the filter optimizer 101 may select the combination of spatial redundancy and suppression of filter weights to generate optimized convolution filters 103, as this results in an instance of the convolution logic 104 that uses the least amount of power.

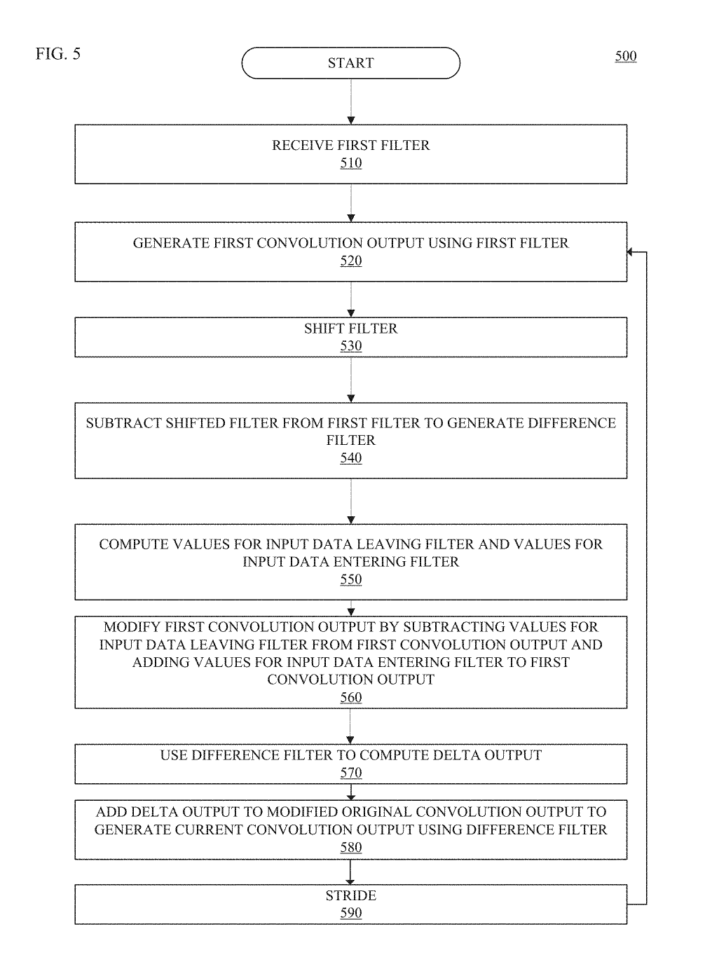

FIG. 5 illustrates an embodiment of a logic flow 500. The logic flow 500 may be representative of some or all of the operations executed by one or more embodiments described herein. For example, the logic flow 500 may represent operations performed by the filter optimizer 101 and/or the convolution logic 104 to reduce spatial redundancy in optimized convolution filters 103 and perform a convolution operation based on the optimized filter 103. Embodiments are not limited in this context.

In the illustrated embodiment shown in FIG. 5, the logic flow 500 may begin at block 510. At block 510, the filter optimizer 101 may receive a first convolution filter 102-1. At block 520, the convolution logic 104 may generate a first convolution output (e.g., products, dot products, etc.) based on the weights of the first filter applied to a first portion of convolution input data 105 (e.g., the first filter weights applied to regions 205, 206 of FIG. 2A). At block 530, the first filter is shifted by a stride. At block 540, the convolution logic 104 may subtract the values of the shifted filter from the values of the first filter to generate a difference filter 204. At block 550, the convolution logic 104 determines values for the input data leaving the first filter (e.g., the product of the first filter and region 205) and computes values for input data entering the first filter (e.g., the product of the first filter and region 207).

At block 560, the convolution logic 104 may modify the first convolution output. More specifically, the convolution logic 104 may subtract convolution values computed at block 550 for data leaving the difference filter 204 from the first convolution output, and add convolution values computed at block 550 for data entering the difference filter 204 to the first convolution output. At block 570, the difference filter 204 is used to compute a delta output on the input data (e.g., the difference filter 204 applied to region 206). At block 580, the output of blocks 560 and 570 are added to generate a convolution output using the difference filter 204. At block 590, the logic flow may return to block 520, where the convolution operation may continue for additional input data 105 (if any). If no additional input data remains, the logic flow 500 may end.

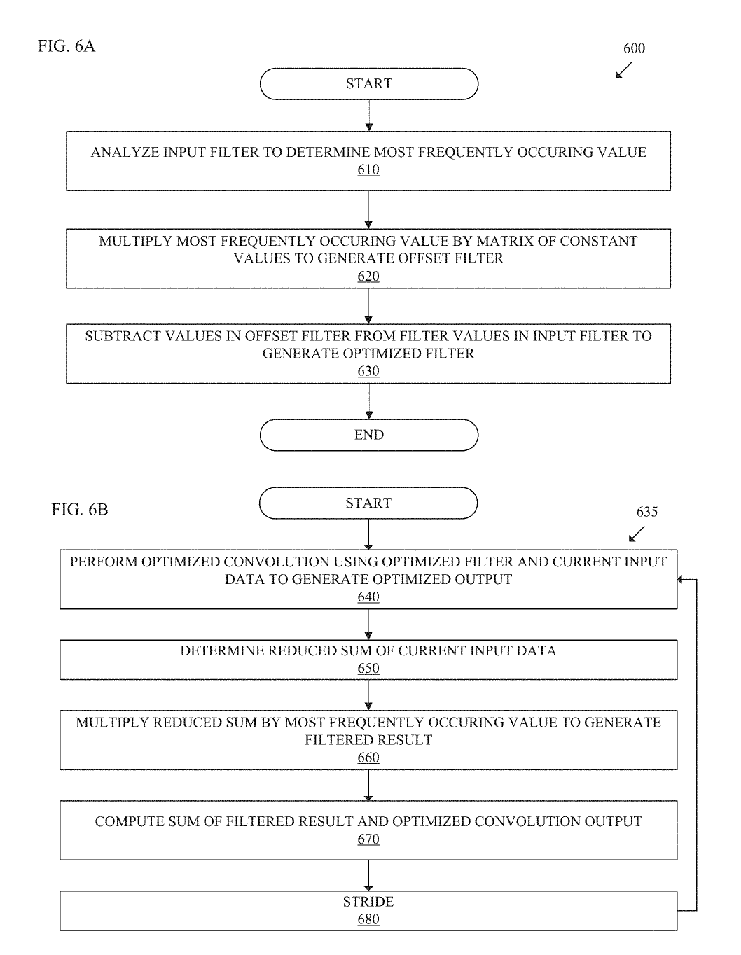

FIG. 6A illustrates an embodiment of a logic flow 600. The logic flow 600 may be representative of some or all of the operations executed by one or more embodiments described herein. For example, the filter optimizer 101 may perform the logic flow 600 to generate an optimized convolution filter 103 by suppressing filter weights. Embodiments are not limited in this context.

In the illustrated embodiment shown in FIG. 6A, the logic flow 600 may begin at block 610. At block 610, the filter optimizer 101 may analyze an input filter to determine the most frequently occurring value therein. For example, the filter optimizer 101 may generate a histogram of the values in the input filter. The filter analyzed at block 610 may be a convolution filter 102 and/or an optimized convolution filter 103. At block 620, the filter optimizer 101 may multiply the most frequently occurring value identified at block 610 to a constant matrix (e.g., where the values of constant matrix are 1) to generate an offset filter. At block 630, the filter optimizer 101 subtracts the offset filter generated at block 620 from the input filter received at block 610 to generate an optimized filter 103. As stated, in addition, the convolution logic 104 may be generated based on the optimized filter 103, where the convolution logic 104 is itself optimized to include fewer instructions based on the optimizations of the optimized convolution filter 103.

FIG. 6B illustrates an embodiment of a logic flow 635. The logic flow 635 may be representative of some or all of the operations executed by one or more embodiments described herein. For example, the convolution logic 104 may perform the logic flow 635 to perform a convolution using the optimized filter generated by the logic flow 600. Embodiments are not limited in this context.

In the illustrated embodiment shown in FIG. 6B, the logic flow 635 may begin at block 640. At block 640, the convolution logic 104 may perform an optimized convolution using the optimized filter generated at block 630 and current input convolution data 105. At block 650, the convolution logic 104 may determine a reduced sum of the current input data 105 (e.g., sum each value of the current input data). At block 660, the convolution logic 104 may multiply the reduced sum computed at block 650 with the most frequently occurring value of the input filter determined at block 610 to generate a filtered result. At block 670, the convolution logic 104 computes a sum of the filtered result generated at block 660 and the optimized convolution output generated at block 640. The output of block 670 is the convolution output for the current input data using an optimized convolution filter 103. If additional input data remains, a stride of the input data is performed at block 680, and the logic flow 635 returns to block 610. If no additional input data remains, the logic flow 635 may end.

FIG. 7 illustrates an embodiment of a storage medium 700. Storage medium 800 may comprise any non-transitory computer-readable storage medium or machine-readable storage medium, such as an optical, magnetic or semiconductor storage medium. In various embodiments, storage medium 700 may comprise an article of manufacture. In some embodiments, storage medium 700 may store computer-executable instructions, such as computer-executable instructions to implement one or more of logic flows or operations described herein, such as with respect to 300, 400, 500, 600, and 635 of FIGS. 3-6. The storage medium 700 may further store computer-executable instructions to implement the filter optimizer 101 and the convolution logic 104. Examples of a computer-readable storage medium or machine-readable storage medium may include any tangible media capable of storing electronic data, including volatile memory or non-volatile memory, removable or non-removable memory, erasable or non-erasable memory, writeable or re-writeable memory, and so forth. Examples of computer-executable instructions may include any suitable type of code, such as source code, compiled code, interpreted code, executable code, static code, dynamic code, object-oriented code, visual code, and the like. The embodiments are not limited in this context.

FIG. 8 illustrates an embodiment of an exemplary computing architecture 800 that may be suitable for implementing various embodiments as previously described. In various embodiments, the computing architecture 800 may comprise or be implemented as part of an electronic device. In some embodiments, the computing architecture 800 may be representative, for example, of a computer system that implements one or more components of system 100 of FIG. 1 and FIGS. 2A-2D. The embodiments are not limited in this context. More generally, the computing architecture 800 is configured to implement all logic, systems, logic flows, methods, apparatuses, and functionality described herein and with reference to FIGS. 1-7.

As used in this application, the terms “system” and “component” and “module” are intended to refer to a computer-related entity, either hardware, a combination of hardware and software, software, or software in execution, examples of which are provided by the exemplary computing architecture 800. For example, a component can be, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

The computing architecture 800 includes various common computing elements, such as one or more processors, multi-core processors, co-processors, memory units, chipsets, controllers, peripherals, interfaces, oscillators, timing devices, video cards, audio cards, multimedia input/output (I/O) components, power supplies, and so forth. The embodiments, however, are not limited to implementation by the computing architecture 800.

As shown in FIG. 8, the computing architecture 800 comprises a processing unit 804, a system memory 806 and a system bus 808. The processing unit 804 can be any of various commercially available processors, including without limitation an AMD® Athlon®, Duron® and Opteron® processors; ARM® application, embedded and secure processors; IBM® and Motorola® DragonBall® and PowerPC® processors; IBM and Sony® Cell processors; Intel® Celeron®, Core®, Core (2) Duo®, Itanium®, Pentium®, Xeon®, and XScale® processors; and similar processors. Dual microprocessors, multi-core processors, and other multi-processor architectures may also be employed as the processing unit 804.

The system bus 808 provides an interface for system components including, but not limited to, the system memory 806 to the processing unit 804. The system bus 808 can be any of several types of bus structure that may further interconnect to a memory bus (with or without a memory controller), a peripheral bus, and a local bus using any of a variety of commercially available bus architectures. Interface adapters may connect to the system bus 808 via a slot architecture. Example slot architectures may include without limitation Accelerated Graphics Port (AGP), Card Bus, (Extended) Industry Standard Architecture ((E)ISA), Micro Channel Architecture (MCA), NuBus, Peripheral Component Interconnect (Extended) (PCI(X)), PCI Express, Personal Computer Memory Card International Association (PCMCIA), and the like.

The system memory 806 may include various types of computer-readable storage media in the form of one or more higher speed memory units, such as read-only memory (ROM), random-access memory (RAM), dynamic RAM (DRAM), Double-Data-Rate DRAM (DDRAM), synchronous DRAM (SDRAM), bulk byte-addressable persistent memory (PMEM), static RAM (SRAM), programmable ROM (PROM), erasable programmable ROM (EPROM), electrically erasable programmable ROM (EEPROM), flash memory (e.g., one or more flash arrays), polymer memory such as ferroelectric polymer memory, ovonic memory, phase change or ferroelectric memory, silicon-oxide-nitride-oxide-silicon (SONOS) memory, magnetic or optical cards, an array of devices such as Redundant Array of Independent Disks (RAID) drives, solid state memory devices (e.g., USB memory, solid state drives (SSD) and any other type of storage media suitable for storing information. In the illustrated embodiment shown in FIG. 8, the system memory 806 can include non-volatile memory 810 and/or volatile memory 812. A basic input/output system (BIOS) can be stored in the non-volatile memory 810.

The computer 802 may include various types of computer-readable storage media in the form of one or more lower speed memory units, including an internal (or external) hard disk drive (HDD) 814, a magnetic floppy disk drive (FDD) 816 to read from or write to a removable magnetic disk 818, and an optical disk drive 820 to read from or write to a removable optical disk 822 (e.g., a compact disc read-only memory (CD-ROM) or digital versatile disc (DVD). The HDD 814, FDD 816 and optical disk drive 820 can be connected to the system bus 808 by a HDD interface 824, an FDD interface 826 and an optical drive interface 828, respectively. The HDD interface 824 for external drive implementations can include at least one or both of Universal Serial Bus (USB) and IEEE 1394 interface technologies.

The drives and associated computer-readable media provide volatile and/or nonvolatile storage of data, data structures, computer-executable instructions, and so forth. For example, a number of program modules can be stored in the drives and memory units 810, 812, including an operating system 830, one or more application programs 832, other program modules 834, and program data 836. In one embodiment, the one or more application programs 832, other program modules 834, and program data 836 can include, for example, the various applications and/or components of the filter optimizer 101, convolution filters 102, optimized convolution filters 103, convolution logic 104, convolution input 105, and convolution output 106, and/or other logic described herein.

A user can enter commands and information into the computer 802 through one or more wire/wireless input devices, for example, a keyboard 838 and a pointing device, such as a mouse 840. Other input devices may include microphones, infra-red (IR) remote controls, radio-frequency (RF) remote controls, game pads, stylus pens, card readers, dongles, finger print readers, gloves, graphics tablets, joysticks, keyboards, retina readers, touch screens (e.g., capacitive, resistive, etc.), trackballs, trackpads, sensors, styluses, and the like. These and other input devices are often connected to the processing unit 804 through an input device interface 842 that is coupled to the system bus 808, but can be connected by other interfaces such as a parallel port, IEEE 1394 serial port, a game port, a USB port, an IR interface, and so forth.

A monitor 844 or other type of display device is also connected to the system bus 808 via an interface, such as a video adaptor 846. The monitor 844 may be internal or external to the computer 802. In addition to the monitor 844, a computer typically includes other peripheral output devices, such as speakers, printers, and so forth.

The computer 802 may operate in a networked environment using logical connections via wire and/or wireless communications to one or more remote computers, such as a remote computer 848. In various embodiments, one or more migrations may occur via the networked environment. The remote computer 848 can be a workstation, a server computer, a router, a personal computer, portable computer, microprocessor-based entertainment appliance, a peer device or other common network node, and typically includes many or all of the elements described relative to the computer 802, although, for purposes of brevity, only a memory/storage device 850 is illustrated. The logical connections depicted include wire/wireless connectivity to a local area network (LAN) 852 and/or larger networks, for example, a wide area network (WAN) 854. Such LAN and WAN networking environments are commonplace in offices and companies, and facilitate enterprise-wide computer networks, such as intranets, all of which may connect to a global communications network, for example, the Internet.

When used in a LAN networking environment, the computer 802 is connected to the LAN 852 through a wire and/or wireless communication network interface or adaptor 856. The adaptor 856 can facilitate wire and/or wireless communications to the LAN 852, which may also include a wireless access point disposed thereon for communicating with the wireless functionality of the adaptor 856.

When used in a WAN networking environment, the computer 802 can include a modem 858, or is connected to a communications server on the WAN 854, or has other means for establishing communications over the WAN 854, such as by way of the Internet. The modem 858, which can be internal or external and a wire and/or wireless device, connects to the system bus 808 via the input device interface 842. In a networked environment, program modules depicted relative to the computer 802, or portions thereof, can be stored in the remote memory/storage device 850. It will be appreciated that the network connections shown are exemplary and other means of establishing a communications link between the computers can be used.

The computer 802 is operable to communicate with wire and wireless devices or entities using the IEEE 802 family of standards, such as wireless devices operatively disposed in wireless communication (e.g., IEEE 802.16 over-the-air modulation techniques). This includes at least Wi-Fi (or Wireless Fidelity), WiMax, and Bluetooth™ wireless technologies, among others. Thus, the communication can be a predefined structure as with a conventional network or simply an ad hoc communication between at least two devices. Wi-Fi networks use radio technologies called IEEE 802.11x (a, b, g, n, etc.) to provide secure, reliable, fast wireless connectivity. A Wi-Fi network can be used to connect computers to each other, to the Internet, and to wire networks (which use IEEE 802.3-related media and functions).

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that make the logic or processor.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may include an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, yet still co-operate or interact with each other.

In addition, in the foregoing Detailed Description, various features are grouped together in a single example to streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code to reduce the number of times code must be retrieved from bulk storage during execution. The term “code” covers a broad range of software components and constructs, including applications, drivers, processes, routines, methods, modules, firmware, microcode, and subprograms. Thus, the term “code” may be used to refer to any collection of instructions which, when executed by a processing system, perform a desired operation or operations.

Logic circuitry, devices, and interfaces herein described may perform functions implemented in hardware and implemented with code executed on one or more processors. Logic circuitry refers to the hardware or the hardware and code that implements one or more logical functions. Circuitry is hardware and may refer to one or more circuits. Each circuit may perform a particular function. A circuit of the circuitry may comprise discrete electrical components interconnected with one or more conductors, an integrated circuit, a chip package, a chip set, memory, or the like. Integrated circuits include circuits created on a substrate such as a silicon wafer and may comprise components. And integrated circuits, processor packages, chip packages, and chipsets may comprise one or more processors.

Processors may receive signals such as instructions and/or data at the input(s) and process the signals to generate the at least one output. While executing code, the code changes the physical states and characteristics of transistors that make up a processor pipeline. The physical states of the transistors translate into logical bits of ones and zeros stored in registers within the processor. The processor can transfer the physical states of the transistors into registers and transfer the physical states of the transistors to another storage medium.

A processor may comprise circuits to perform one or more sub-functions implemented to perform the overall function of the processor. One example of a processor is a state machine or an application-specific integrated circuit (ASIC) that includes at least one input and at least one output. A state machine may manipulate the at least one input to generate the at least one output by performing a predetermined series of serial and/or parallel manipulations or transformations on the at least one input.

The logic as described above may be part of the design for an integrated circuit chip. The chip design is created in a graphical computer programming language, and stored in a computer storage medium or data storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication.

The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a processor board, a server platform, or a motherboard, or (b) an end product.

The following examples pertain to further embodiments, from which numerous permutations and configurations will be apparent.

Example 1 is an apparatus, comprising: a processor circuit; and a memory storing instructions which when executed by the processor circuit cause the processor circuit to: determine, based on an analysis of a plurality of values of a convolution filter, an optimization operation to optimize at least one value of the plurality of values of the convolution filter; perform the optimization operation on the values of the convolution filter to generate an optimized convolution filter; and perform a convolution operation by a convolution logic based on the optimized convolution filter and an input data.

Example 2 includes the subject matter of example 1, the optimization operation to generate a difference filter, the analysis based at least in part on a spatial correlation of the plurality of values of the convolution filter, the memory storing instructions which when executed by the processor circuit cause the processor circuit to: shift the plurality of values of the convolution filter; generate the difference filter by subtracting the shifted plurality of values of the convolution filter from the convolution filter, the at least two of a plurality of values of the difference filter having identical values; and perform the convolution operation based at least in part on the difference filter.

Example 3 includes the subject matter of example 2, the memory storing instructions which when executed by the processor circuit cause the processor circuit to: receive a prior convolution output comprising a product of the convolution filter and a window of the input data; shift the window of the input data by a stride; subtract, from the prior convolution output, a product of an input data exiting the window as a result of the stride and the convolution filter to generate a first modified prior convolution output; add, to the modified prior convolution output, a product of an input data entering the window as a result of the stride and the convolution filter to generate a second modified prior convolution output; compute a difference product of the difference filter and the shifted window of the input data; and add the difference product to the second modified prior convolution output to perform the convolution operation based at least in part on the difference filter.

Example 4 includes the subject matter of example 2, the memory storing instructions which when executed by the processor circuit cause the processor circuit to: identify, based on the analysis, a first value of the plurality of values of the difference filter having a greater frequency of occurrence in the difference filter relative to other values in the difference filter, the optimization operation comprising instructions which when executed by the processor circuit cause the processor circuit to: multiply the first value of the plurality of values by a matrix of constant values to generate an offset filter; and subtract the offset filter from the difference filter to generate an optimized difference filter; and perform the convolution operation based at least in part on the optimized difference filter.

Example 5 includes the subject matter of example 4, the memory storing instructions which when executed by the processor circuit cause the processor circuit to: compute a product of the optimized difference filter and a current window of the input data; compute a sum of a plurality of values of the current window of the input data; compute a product of the offset filter and the computed sum by the first value to generate a filtered result; and compute a sum of the filtered result and the computed product of the optimized difference filter and the current window of the input data to perform the convolution operation based at least in part on the optimized difference filter.

Example 6 includes the subject matter of example 1, wherein the convolution logic comprises one or more of: (i) a machine learning algorithm, (ii) a neural network, and (iii) a signal processing logic, the memory storing instructions which when executed by the processor circuit cause the processor circuit to: determine a performance indicator comprising one or more of: (i) a number of instructions of the convolution logic, (ii) an amount of time, (iii) an amount of power, and (iv) an amount of computing resources required to perform the convolution operation using the optimized convolution filter; and select the optimization operation based on the determined performance indicator.

Example 7 includes the subject matter of example 6, the optimized convolution filter generated based on a first optimization operation, the memory storing instructions which when executed by the processor circuit cause the processor circuit to: determine a performance indicator comprising one or more of: (i) a number of instructions of the convolution logic, (ii) an amount of time, (iii) an amount of power, and (iv) an amount of computing resources required to perform the convolution operation using a second optimized convolution filter generated based on a second optimization operation; determine a performance indicator comprising one or more of: (i) a number of instructions of the convolution logic, (ii) an amount of time, (iii) an amount of power, and (iv) an amount of computing resources required to perform the convolution operation using a third optimized convolution filter generated based on the first and second optimization operations; and select at least one of the first, the second, and the third optimization operations based on the determined performance indicators.

Example 8 includes the subject matter of example 1, the memory storing instructions which when executed by the processor circuit cause the processor circuit to: generate, by a compiler, an executable code for the convolution logic based on the optimized convolution filter, the generated executable code for the convolution logic having fewer instructions than an executable code generated for the convolution logic based on the convolution filter.

Example 9 includes the subject matter of example 8, the compiler comprising instructions which when executed by the processor circuit cause the processor circuit to: determine that implementing the convolution logic based on the optimized convolution filter includes at least one operation comprising: (i) a multiply by zero operation, (ii) an add by zero operation, and (iii) a multiply and accumulate operation on a zero value; refrain from generating an executable code statement for the determined at least one operation; and generate the executable code for the convolution logic based on the optimized convolution filter to not include the executable code statement for the determined at least one operation.

Example 10 includes the subject matter of example 1, the memory storing instructions which when executed by the processor circuit cause the processor circuit to: identify, based on the analysis, a first value of the plurality of values of the convolution filter having a greater frequency of occurrence in the convolution filter relative to other values in the convolution filter, the optimization operation comprising instructions that when executed by the computing device cause the computing device to: multiply the plurality of values in the convolution filter by the first value of the plurality of values to generate an offset filter; and subtract the offset filter from the convolution filter to generate the optimized convolution filter; and perform the convolution operation based at least in part on the optimized convolution filter.

Example 11 includes the subject matter of example 10, the memory storing instructions which when executed by the processor circuit cause the processor circuit to: compute a product of the optimized convolution filter and a current window of the input data; compute a sum of a plurality of values of the current window of the input data; compute a product of the offset filter and the computed sum by the first value to generate a filtered result; and compute a sum of the filtered result and the computed product of the optimized convolution filter and the current window of the input data to perform the convolution operation based at least in part on the optimized convolution filter.

Example 12 is a non-transitory computer-readable storage medium comprising instructions that when executed by a computing device, cause the computing device to: determine, based on an analysis of a plurality of values of a convolution filter, an optimization operation to optimize at least one value of the plurality of values of the convolution filter; perform the optimization operation on the values of the convolution filter to generate an optimized convolution filter; and perform a convolution operation by a convolution logic based on the optimized convolution filter and an input data.

Example 13 includes the subject matter of example 12, the optimization operation to generate a difference filter, the analysis based at least in part on a spatial correlation of the plurality of values of the convolution filter, further comprising instructions that when executed by the computing device, cause the computing device to: shift the plurality of values of the convolution filter; generate the difference filter by subtracting the shifted plurality of values of the convolution filter from the convolution filter, the at least two of a plurality of values of the difference filter having identical values; and perform the convolution operation based at least in part on the difference filter.

Example 14 includes the subject matter of example 13, further comprising instructions that when executed by the computing device, cause the computing device to: receive a prior convolution output comprising a product of the convolution filter and a window of the input data; shift the window of the input data by a stride; subtract, from the prior convolution output, a product of an input data exiting the window as a result of the stride and the convolution filter to generate a first modified prior convolution output; add, to the modified prior convolution output, a product of an input data entering the window as a result of the stride and the convolution filter to generate a second modified prior convolution output; compute a difference product of the difference filter and the shifted window of the input data; and add the difference product to the second modified prior convolution output to perform the convolution operation based at least in part on the difference filter.

Example 15 includes the subject matter of example 13, further comprising instructions that when executed by the computing device, cause the computing device to: identify, based on the analysis, a first value of the plurality of values of the difference filter having a greater frequency of occurrence in the difference filter relative to other values in the difference filter, the optimization operation comprising instructions which when executed by the processor circuit cause the processor circuit to: multiply the first value of the plurality of values by a matrix of constant values to generate an offset filter; and subtract the offset filter from the difference filter to generate an optimized difference filter; and perform the convolution operation based at least in part on the optimized difference filter.

Example 16 includes the subject matter of example 15, further comprising instructions that when executed by the computing device, cause the computing device to: compute a product of the optimized difference filter and a current window of the input data; compute a sum of a plurality of values of the current window of the input data; compute a product of the offset filter and the computed sum by the first value to generate a filtered result; and compute a sum of the filtered result and the computed product of the optimized difference filter and the current window of the input data to perform the convolution operation based at least in part on the optimized difference filter.

Example 17 includes the subject matter of example 12, further comprising instructions that when executed by the computing device, cause the computing device to: identify, based on the analysis, a first value of the plurality of values of the convolution filter having a greater frequency of occurrence in the convolution filter relative to other values in the convolution filter, the optimization operation comprising instructions that when executed by the computing device cause the computing device to: multiply the plurality of values in the convolution filter by the first value of the plurality of values to generate an offset filter; and subtract the offset filter from the convolution filter to generate the optimized convolution filter; and perform the convolution operation based at least in part on the optimized convolution filter.

Example 18 includes the subject matter of example 17, further comprising instructions that when executed by the computing device, cause the computing device to: compute a product of the optimized convolution filter and a current window of the input data; compute a sum of a plurality of values of the current window of the input data; compute a product of the offset filter and the computed sum by the first value to generate a filtered result; and compute a sum of the filtered result and the computed product of the optimized convolution filter and the current window of the input data to perform the convolution operation based at least in part on the optimized convolution filter.

Example 19 includes the subject matter of example 12, further comprising instructions that when executed by the computing device, cause the computing device to: determine a performance indicator comprising one or more of: (i) a number of instructions of the convolution logic, (ii) an amount of time, (iii) an amount of power, and (iv) an amount of computing resources required to perform the convolution operation using the optimized convolution filter; and select the optimization operation based on the determined performance indicator.

Example 20 includes the subject matter of example 19, the optimized convolution filter generated based on a first optimization operation, further comprising instructions that when executed by the computing device, cause the computing device to: determine a performance indicator comprising one or more of: (i) a number of instructions of the convolution logic, (ii) an amount of time, (iii) an amount of power, and (iv) an amount of computing resources required to perform the convolution operation using a second optimized convolution filter generated based on a second optimization operation; determine a performance indicator comprising one or more of: (i) a number of instructions of the convolution logic, (ii) an amount of time, (iii) an amount of power, and (iv) an amount of computing resources required to perform the convolution operation using a third optimized convolution filter generated based on the first and second optimization operations; and select at least one of the first, the second, and the third optimization operations based on the determined performance indicators.

Example 21 includes the subject matter of example 12, further comprising instructions that when executed by the computing device, cause the computing device to: generate, by a compiler, an executable code for the convolution logic based on the optimized convolution filter, the generated executable code for the convolution logic having fewer instructions than an executable code generated for the convolution logic based on the convolution filter.

Example 22 includes the subject matter of example 21, further comprising instructions that when executed by the computing device, cause the computing device to: determine that implementing the convolution logic based on the optimized convolution filter includes at least one operation comprising: (i) a multiply by zero operation, (ii) an add by zero operation, and (iii) a multiply and accumulate operation on a zero value; refrain from generating an executable code statement for the determined at least one operation; and generate the executable code for the convolution logic based on the optimized convolution filter to not include the executable code statement for the determined at least one operation.

Example 23 is a method, comprising: determining, based on an analysis of a plurality of values of a convolution filter, an optimization operation to optimize at least one value of the plurality of values of the convolution filter; performing the optimization operation on the values of the convolution filter to generate an optimized convolution filter; and performing, by operation of a computer processor, a convolution operation by a convolution logic based on the optimized convolution filter and an input data.

Example 24 includes the subject matter of example 23, the optimization operation comprising generating a difference filter, the analysis based at least in part on a spatial correlation of the plurality of values of the convolution filter, wherein the convolution logic comprises one or more of: (i) a machine learning algorithm, (ii) a neural network, and (iii) a signal processing logic, the method further comprising: shifting the plurality of values of the convolution filter; generating the difference filter by subtracting the shifted plurality of values of the convolution filter from the convolution filter, the at least two of a plurality of values of the difference filter having identical values; and performing the convolution operation based at least in part on the difference filter.

Example 25 includes the subject matter of example 24, further comprising: receiving a prior convolution output comprising a product of the convolution filter and a window of the input data; shifting the window of the input data by a stride; subtracting, from the prior convolution output, a product of an input data exiting the window as a result of the stride and the convolution filter to generate a first modified prior convolution output; adding, to the modified prior convolution output, a product of an input data entering the window as a result of the stride and the convolution filter to generate a second modified prior convolution output; computing a difference product of the difference filter and the shifted window of the input data; and adding the difference product to the second modified prior convolution output to perform the convolution operation based at least in part on the difference filter.

Example 26 includes the subject matter of example 25, further comprising: identifying, based on the analysis, a first value of the plurality of values of the difference filter having a greater frequency of occurrence in the difference filter relative to other values in the difference filter, the optimization operation comprising: multiplying the first value of the plurality of values by a matrix of constant values to generate an offset filter; and subtracting the offset filter from the difference filter to generate an optimized difference filter; and performing the convolution operation based at least in part on the optimized difference filter.

Example 27 includes the subject matter of example 26, further comprising: computing a product of the optimized difference filter and a current window of the input data; computing a sum of a plurality of values of the current window of the input data; computing a product of the offset filter and the computed sum by the first value to generate a filtered result; and computing a sum of the filtered result and the computed product of the optimized difference filter and the current window of the input data to perform the convolution operation based at least in part on the optimized difference filter.

Example 28 includes the subject matter of example 23, wherein the convolution logic comprises one or more of: (i) a machine learning algorithm, (ii) a neural network, and (iii) a signal processing logic, the method further comprising: determining a performance indicator comprising one or more of: (i) a number of instructions of the convolution logic, (ii) an amount of time, (iii) an amount of power, and (iv) an amount of computing resources required to perform the convolution operation using the optimized convolution filter; and selecting the optimization operation based on the determined performance indicator.

Example 29 includes the subject matter of example 28, the optimized convolution filter generated based on a first optimization operation, the method further comprising: determining a performance indicator comprising one or more of: (i) a number of instructions of the convolution logic, (ii) an amount of time, (iii) an amount of power, and (iv) an amount of computing resources required to perform the convolution operation using a second optimized convolution filter generated based on a second optimization operation; determining a performance indicator comprising one or more of: (i) a number of instructions of the convolution logic, (ii) an amount of time, (iii) an amount of power, and (iv) an amount of computing resources required to perform the convolution operation using a third optimized convolution filter generated based on the first and second optimization operations; and selecting at least one of the first, second, and third optimization operations based on the determined performance indicators.

Example 30 includes the subject matter of example 23, further comprising: identifying, based on the analysis, a first value of the plurality of values of the convolution filter having a greater frequency of occurrence in the convolution filter relative to other values in the convolution filter, the optimization operation comprising instructions that when executed by the computing device cause the computing device to: multiplying the first value of the plurality of values by a matrix of constant values to generate an offset filter; and subtracting the offset filter from the convolution filter to generate the optimized convolution filter; and performing the convolution operation based at least in part on the optimized convolution filter.

Example 31 includes the subject matter of example 30, further comprising: computing a product of the optimized convolution filter and a current window of the input data; computing a sum of a plurality of values of the current window of the input data; computing a product of the offset filter and the computed sum by the first value to generate a filtered result; and computing a sum of the filtered result and the computed product of the optimized convolution filter and the current window of the input data to perform the convolution operation based at least in part on the optimized convolution filter.

Example 32 includes the subject matter of example 23, further comprising: generating, by a compiler, an executable code for the convolution logic based on the optimized convolution filter, the generated executable code for the convolution logic having fewer instructions than an executable code generated for the convolution logic based on the convolution filter.

Example 33 includes the subject matter of example 32, further comprising: determining that implementing the convolution logic based on the optimized convolution filter includes at least one operation comprising: (i) a multiply by zero operation, (ii) an add by zero operation, and (iii) a multiply and accumulate operation on a zero value; refraining from generating an executable code statement for the determined at least one operation; and generating the executable code for the convolution logic based on the optimized convolution filter to not include the executable code statement for the determined at least one operation.

Example 34 is an apparatus comprising: means for determining, based on an analysis of a plurality of values of a convolution filter, an optimization operation to optimize at least one value of the plurality of values of the convolution filter; means for performing the optimization operation on the values of the convolution filter to generate an optimized convolution filter; and means for performing a convolution operation by a convolution logic based on the optimized convolution filter and an input data.

Example 35 includes the subject matter of example 34, the analysis based at least in part on a spatial correlation of the plurality of values of the convolution filter, further comprising: means for shifting the plurality of values of the convolution filter; means for generating a difference filter by subtracting the shifted plurality of values of the convolution filter from the convolution filter, the at least two of a plurality of values of the difference filter having identical values; and means for performing the convolution operation based at least in part on the difference filter.

Example 36 includes the subject matter of example 35, further comprising: means for receiving a prior convolution output comprising a product of the convolution filter and a window of the input data; means for shifting the window of the input data by a stride; means for subtracting, from the prior convolution output, a product of an input data exiting the window as a result of the stride and the convolution filter to generate a first modified prior convolution output; means for adding, to the modified prior convolution output, a product of an input data entering the window as a result of the stride and the convolution filter to generate a second modified prior convolution output; means for computing a difference product of the difference filter and the shifted window of the input data; and means for adding the difference product to the second modified prior convolution output to perform the convolution operation based at least in part on the difference filter.

Example 37 includes the subject matter of example 35, further comprising: means for identifying, based on the analysis, a first value of the plurality of values of the difference filter having a greater frequency of occurrence in the difference filter relative to other values in the difference filter; means for multiplying the first value of the plurality of values by a matrix of constant values to generate an offset filter; means for subtracting the offset filter from the difference filter to generate an optimized difference filter; and means for performing the convolution operation based at least in part on the optimized difference filter.

Example 38 includes the subject matter of example 37, further comprising: means for computing a product of the optimized difference filter and a current window of the input data; means for computing a sum of a plurality of values of the current window of the input data; means for computing a product of the offset filter and the computed sum by the first value to generate a filtered result; and means for computing a sum of the filtered result and the computed product of the optimized difference filter and the current window of the input data to perform the convolution operation based at least in part on the optimized difference filter.

Example 39 includes the subject matter of example 34, wherein the convolution logic comprises one or more of: (i) a machine learning algorithm, (ii) a neural network, and (iii) a signal processing logic, the apparatus further comprising: means for determining a performance indicator comprising one or more of: (i) a number of instructions of the convolution logic, (ii) an amount of time, (iii) an amount of power, and (iv) an amount of computing resources required to perform the convolution operation using the optimized convolution filter; and means for selecting the optimization operation based on the determined performance indicator.

Example 40 includes the subject matter of example 39, the optimized convolution filter generated based on a first optimization operation, the apparatus further comprising means for determining a performance indicator comprising one or more of: (i) a number of instructions of the convolution logic, (ii) an amount of time, (iii) an amount of power, and (iv) an amount of computing resources required to perform the convolution operation using a second optimized convolution filter generated based on a second optimization operation; means for determining a performance indicator comprising one or more of: (i) a number of instructions of the convolution logic, (ii) an amount of time, (iii) an amount of power, and (iv) an amount of computing resources required to perform the convolution operation using a third optimized convolution filter generated based on the first and second optimization operations; and means for selecting at least one of the first and second optimization operations based on the determined performance indicators.

Example 41 includes the subject matter of example 34, further comprising means for generating an executable code for the convolution logic based on the optimized convolution filter, the generated executable code for the convolution logic having fewer instructions than an executable code generated for the convolution logic based on the convolution filter.

Example 42 includes the subject matter of example 41, further comprising: means for determining that implementing the convolution logic based on the optimized convolution filter includes at least one operation comprising: (i) a multiply by zero operation, (ii) an add by zero operation, and (iii) a multiply and accumulate operation on a zero value; means for refraining from generating an executable code statement for the determined at least one operation; and means for generating the executable code for the convolution logic based on the optimized convolution filter to not include the executable code statement for the determined at least one operation.

Example 43 includes the subject matter of example 34, further comprising: means for identifying, based on the analysis, a first value of the plurality of values of the convolution filter having a greater frequency of occurrence in the convolution filter relative to other values in the convolution filter, the optimization operation comprising instructions that when executed by the computing device cause the computing device to: means for multiplying the first value of the plurality of values by a matrix of constant values to generate an offset filter; and means for subtracting the offset filter from the convolution filter to generate the optimized convolution filter; and means for performing the convolution operation based at least in part on the optimized convolution filter.

Example 44 includes the subject matter of example 43, further comprising: means for computing a product of the optimized convolution filter and a current window of the input data; means for computing a sum of a plurality of values of the current window of the input data; means for computing a product of the offset filter and the computed sum by the first value to generate a filtered result; and means for computing a sum of the filtered result and the computed product of the optimized convolution filter and the current window of the input data to perform the convolution operation based at least in part on the optimized convolution filter.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An apparatus, comprising:
a processor circuit; and
a memory storing instructions which when executed by the processor circuit cause the processor circuit to:
determine, based on an analysis of a plurality of values of a convolution filter, an optimization operation to optimize at least one value of the plurality of values of the convolution filter;
perform the optimization operation on the values of the convolution filter to generate an optimized convolution filter; and
perform a convolution operation by a convolution logic based on the optimized convolution filter and an input data.

2. The apparatus of claim 1, the optimization operation to generate a difference filter, the analysis based at least in part on a spatial correlation of the plurality of values of the convolution filter, the memory storing instructions which when executed by the processor circuit cause the processor circuit to:
shift the plurality of values of the convolution filter;
generate the difference filter by subtracting the shifted plurality of values of the convolution filter from the convolution filter, the at least two of a plurality of values of the difference filter having identical values; and
perform the convolution operation based at least in part on the difference filter.

3. The apparatus of claim 2, the memory storing instructions which when executed by the processor circuit cause the processor circuit to:
receive a prior convolution output comprising a product of the convolution filter and a window of the input data;
shift the window of the input data by a stride;
subtract, from the prior convolution output, a product of an input data exiting the window as a result of the stride and the convolution filter to generate a first modified prior convolution output;
add, to the modified prior convolution output, a product of an input data entering the window as a result of the stride and the convolution filter to generate a second modified prior convolution output;
compute a difference product of the difference filter and the shifted window of the input data; and
add the difference product to the second modified prior convolution output to perform the convolution operation based at least in part on the difference filter.

4. The apparatus of claim 2, the memory storing instructions which when executed by the processor circuit cause the processor circuit to:
identify, based on the analysis, a first value of the plurality of values of the difference filter having a greater frequency of occurrence in the difference filter relative to other values in the difference filter, the optimization operation comprising instructions which when executed by the processor circuit cause the processor circuit to:
multiply the first value of the plurality of values by a matrix of constant values to generate an offset filter; and
subtract the offset filter from the difference filter to generate an optimized difference filter; and
perform the convolution operation based at least in part on the optimized difference filter.

5. The apparatus of claim 4, the memory storing instructions which when executed by the processor circuit cause the processor circuit to:
compute a product of the optimized difference filter and a current window of the input data;
compute a sum of a plurality of values of the current window of the input data;
compute a product of the offset filter and the computed sum by the first value to generate a filtered result; and
compute a sum of the filtered result and the computed product of the optimized difference filter and the current window of the input data to perform the convolution operation based at least in part on the optimized difference filter.

6. The apparatus of claim 1, wherein the convolution logic comprises one or more of: (i) a machine learning algorithm, (ii) a neural network, (iii) an amount of power, and (iv) a signal processing logic, the memory storing instructions which when executed by the processor circuit cause the processor circuit to:
determine a performance indicator comprising one or more of: (i) a number of instructions of the convolution logic, (ii) an amount of time, (iii) an amount of power, and (iv) an amount of computing resources required to perform the convolution operation using the optimized convolution filter; and
select the optimization operation based on the determined performance indicator.

7. The apparatus of claim 6, the optimized convolution filter generated based on a first optimization operation, the memory storing instructions which when executed by the processor circuit cause the processor circuit to:
determine a performance indicator comprising one or more of: (i) a number of instructions of the convolution logic, (ii) an amount of time, (iii) an amount of power, and (iv) an amount of computing resources required to perform the convolution operation using a second optimized convolution filter generated based on a second optimization operation;
determine a performance indicator comprising one or more of: (i) a number of instructions of the convolution logic, (ii) an amount of time, (iii) an amount of power, and (iv) an amount of computing resources required to perform the convolution operation using a third optimized convolution filter generated based on the first and second optimization operations; and
select at least one of the first, the second, and the third optimization operations based on the determined performance indicators.

8. The apparatus of claim 1, the memory storing instructions which when executed by the processor circuit cause the processor circuit to:
generate, by a compiler, an executable code for the convolution logic based on the optimized convolution filter, the generated executable code for the convolution logic having fewer instructions than an executable code generated for the convolution logic based on the convolution filter.

9. The apparatus of claim 8, the compiler comprising instructions which when executed by the processor circuit cause the processor circuit to:
determine that implementing the convolution logic based on the optimized convolution filter includes at least one operation comprising: (i) a multiply by zero operation, (ii) an add by zero operation, and (iii) a multiply and accumulate operation on a zero value;
refrain from generating an executable code statement for the determined at least one operation; and
generate the executable code for the convolution logic based on the optimized convolution filter to not include the executable code statement for the determined at least one operation.

10. A non-transitory computer-readable storage medium comprising instructions that when executed by a computing device, cause the computing device to:
determine, based on an analysis of a plurality of values of a convolution filter, an optimization operation to optimize at least one value of the plurality of values of the convolution filter;
perform the optimization operation on the values of the convolution filter to generate an optimized convolution filter; and
perform a convolution operation by a convolution logic based on the optimized convolution filter and an input data.

11. The non-transitory computer-readable storage medium of claim 10, the optimization operation to generate a difference filter, the analysis based at least in part on a spatial correlation of the plurality of values of the convolution filter, further comprising instructions that when executed by the computing device, cause the computing device to:
shift the plurality of values of the convolution filter;
generate the difference filter by subtracting the shifted plurality of values of the convolution filter from the convolution filter, the at least two of a plurality of values of the difference filter having identical values; and
perform the convolution operation based at least in part on the difference filter.

12. The non-transitory computer-readable storage medium of claim 11, further comprising instructions that when executed by the computing device, cause the computing device to:
receive a prior convolution output comprising a product of the convolution filter and a window of the input data;
shift the window of the input data by a stride;
subtract, from the prior convolution output, a product of an input data exiting the window as a result of the stride and the convolution filter to generate a first modified prior convolution output;
add, to the modified prior convolution output, a product of an input data entering the window as a result of the stride and the convolution filter to generate a second modified prior convolution output;
compute a difference product of the difference filter and the shifted window of the input data; and
add the difference product to the second modified prior convolution output to perform the convolution operation based at least in part on the difference filter.

13. The non-transitory computer-readable storage medium of claim 10, further comprising instructions that when executed by the computing device, cause the computing device to:
identify, based on the analysis, a first value of the plurality of values of the convolution filter having a greater frequency of occurrence in the convolution filter relative to other values in the convolution filter, the optimization operation comprising instructions that when executed by the computing device cause the computing device to:
multiply the first value of the plurality of values by a matrix of constant values to generate an offset filter; and
subtract the offset filter from the convolution filter to generate the optimized convolution filter; and
perform the convolution operation based at least in part on the optimized convolution filter.

14. The non-transitory computer-readable storage medium of claim 13, further comprising instructions that when executed by the computing device, cause the computing device to:
compute a product of the optimized convolution filter and a current window of the input data;
compute a sum of a plurality of values of the current window of the input data;
compute a product of the offset filter and the computed sum by the first value to generate a filtered result; and
compute a sum of the filtered result and the computed product of the optimized convolution filter and the current window of the input data to perform the convolution operation based at least in part on the optimized convolution filter.

15. The non-transitory computer-readable storage medium of claim 10, further comprising instructions that when executed by the computing device, cause the computing device to:
determine a performance indicator comprising one or more of: (i) a number of instructions of the convolution logic, (ii) an amount of time, (iii) an amount of power, and (iv) an amount of computing resources required to perform the convolution operation using the optimized convolution filter, the optimized convolution filter generated based on a first optimization operation; and
determine a performance indicator comprising one or more of: (i) a number of instructions of the convolution logic, (ii) an amount of time, (iii) an amount of power, and (iv) an amount of computing resources required to perform the convolution operation using a second optimized convolution filter generated based on a second optimization operation;
determine a performance indicator comprising one or more of: (i) a number of instructions of the convolution logic, (ii) an amount of time, (iii) an amount of power, and (iv) an amount of computing resources required to perform the convolution operation using a third optimized convolution filter generated based on the first and second optimization operations; and
select at least one of the first, second, and third optimization operations based on the determined performance indicators,
wherein the convolution logic comprises one or more of: (i) a machine learning algorithm, (ii) a neural network, and (iii) a signal processing logic.

16. The non-transitory computer-readable storage medium of claim 10, further comprising instructions that when executed by the computing device, cause the computing device to:
generate, by a compiler, an executable code for the convolution logic based on the optimized convolution filter, the generated executable code for the convolution logic having fewer instructions than an executable code generated for the convolution logic based on the convolution filter.

17. A method, comprising:
determining, based on an analysis of a plurality of values of a convolution filter, an optimization operation to optimize at least one value of the plurality of values of the convolution filter;
performing the optimization operation on the values of the convolution filter to generate an optimized convolution filter; and
performing, by operation of a computer processor, a convolution operation by a convolution logic based on the optimized convolution filter and an input data.

18. The method of claim 17, the optimization operation comprising generating a difference filter, the analysis based at least in part on a spatial correlation of the plurality of values of the convolution filter, wherein the convolution logic comprises one or more of: (i) a machine learning algorithm, (ii) a neural network, and (iii) a signal processing logic, the method further comprising:
shifting the plurality of values of the convolution filter;
generating the difference filter by subtracting the shifted plurality of values of the convolution filter from the convolution filter, the at least two of a plurality of values of the difference filter having identical values; and
performing the convolution operation based at least in part on the difference filter.

19. The method of claim 18, further comprising:
receiving a prior convolution output comprising a product of the convolution filter and a window of the input data;
shifting the window of the input data by a stride;
subtracting, from the prior convolution output, a product of an input data exiting the window as a result of the stride and the convolution filter to generate a first modified prior convolution output;
adding, to the modified prior convolution output, a product of an input data entering the window as a result of the stride and the convolution filter to generate a second modified prior convolution output;
computing a difference product of the difference filter and the shifted window of the input data; and
adding the difference product to the second modified prior convolution output to perform the convolution operation based at least in part on the difference filter.

20. The method of claim 19, further comprising:
identifying, based on the analysis, a first value of the plurality of values of the difference filter having a greater frequency of occurrence in the difference filter relative to other values in the difference filter, the optimization operation comprising:
multiplying the first value of the plurality of values by a matrix of constant values to generate an offset filter; and
subtracting the offset filter from the difference filter to generate an optimized difference filter; and
performing the convolution operation based at least in part on the optimized difference filter.
